(19) United States
(12) Patent Application Publication
(10) Pub. No.: US 2015/0198674 A1
(43) Pub. Date: Jul. 16, 2015

(54) METHOD AND APPARATUS FOR DETERMINING THE STATE OF BATTERIES

(71) Applicant: TECHNISCHE UNIVERSITÄT BRAUNSCHWEIG, Braunschweig (DE)

(72) Inventors: Thorsten Kroker, Braunschweig (DE); Michael Kurrat, Braunschweig (DE); Ernst-Dieter Wilkening, Braunschweig (DE); Hannes Haupt, Braunschweig (DE)

(73) Assignee: Technische Universitat Braunschweig, Braunschweig (DE)

(21) Appl. No.: 14/415,449

(22) PCT Filed: Jul. 16, 2013
(86) PCT No.: PCT/EP2013/002110

§ 371 Date: Jan. 16, 2015

(30) Foreign Application Priority Data
Jul. 17, 2012 (DE) 10 2012 014 014.2

(51) Int. Cl. G01R 31/36; H01M 10/42; H02J 7/00; H01M 10/48

(52) U.S. Cl. CPC G01R 31/3662; H01M 10/48; H01M 10/4257; H01M 10/486; H02J 7/0047; H01M 2010/4271; H02J 2007/005

(57) ABSTRACT

The present invention relates to a method and a suitable apparatus for determining the state of a rechargeable battery and for checking contact resistances in a battery system. According to the invention, an impedance curve is determined using signals at different frequencies and a value for an area, which results from the impedance curve, is then calculated from a predetermined threshold value and an x axis. The value for the area is a measure of the ageing of the battery. A control signal is generated on the basis thereof. In one preferred embodiment, said control signal is used to drive a signaling apparatus and thus to present the state of the battery to a user. The present invention can be used, for example, in motor vehicles that are electrically driven.

The present invention relates to a method and an associated apparatus for determining the state of rechargeable batteries, in particular lithium ion batteries. The present invention can also serve to determine the quality of contact resistances in a battery system.

Rechargeable batteries are generally known and are also referred to as accumulators in this patent application. Depending on the field of use, they are formed from one or more rechargeable battery cells—also referred to here as accumulator cells—which can be interconnected in parallel and/or in series. Different technologies can be used for this purpose, such as in the case of lithium ion accumulators (Li ion), lead accumulators (Pb), nickel-cadmium accumulators (NiCd), nickel-hydrogen accumulators (NiH₂), nickel metal hydride accumulators (NiMH), lithium polymer accumulators (LiPo), lithium metal accumulators (LiFe), lithium manganese accumulators (LiMn), lithium iron phosphate accumulators (LiFePO₄), lithium titanate accumulators (LiTi), nickel iron accumulators (Ni—Fe), sodium nickel chloride high-temperature batteries (Na/NiCl), silver zinc accumulators, silicon accumulators, vanadium redox accumulators, zinc bromine accumulators, and the like.

In Offenlegungsschrift [Unexamined Patent Application] DE 10 2009 000 337 A1, a method for determining the state of ageing of a battery cell has already been described. In this case, an impedance spectrum of the battery cell is recorded. For this purpose, a sinus-shaped signal of variable frequency is imposed on a battery through its contacts and the complex impedance of the battery cell is determined as a function of the frequency by measuring current and voltage. It is also mentioned there that the measured impedance spectrum can be presented as a Nyquist plot, in which imaginary impedance values are plotted against real impedance values.

In the method presented in DE 10 2009 000 337 A1, the state of ageing and accordingly also prognoses about the still remaining lifetime are to be determined through compilation of a series of reference values for reference battery cells having different states of ageing.

However, it cannot be inferred from the cited unexamined patent application how the remaining lifetime of a rechargeable battery cell is determined as a function of cyclically repeating charging and discharging operations.

Accordingly, the problem of the invention is to determine the state of a rechargeable battery or a rechargeable battery cell. State is understood here to mean, in particular,
the ageing, taking into consideration the number of charging/discharging cycles that have already occurred,
the remaining lifetime, and or
a measure of the quality; what is thus involved here is the extent to which a rechargeable battery cell or battery, which can also be factory new, is or is not defective.

This problem is solved by the method according to the invention in accordance with claim 1 or by the apparatus according to the invention in accordance with the first apparatus claim. Even though, in the following description, the invention is usually described by way of a rechargeable lithium ion battery cell as example, it is in no way limited to it. It can also be used for other rechargeable battery cells, such as, for example, those mentioned above, and also for batteries formed from them.

The present invention is based on the following knowledge.

Lithium ion batteries are used to an increasing extent for electric power supply in motor vehicles and other apparatuses. In this case, these batteries are cyclically charged and discharged. These charging cycles determine the state of ageing and thus also the remaining lifetime markedly more than does purely temporal ageing, which is determined, for example, by one charging operation and to which the above-mentioned Offenlegungsschift (Unexamined Patent Application) DE 10 2009 000 337 A1 relates. It has further been found that a rechargeable battery cell can be represented by an equivalent circuit diagram, such as is shown in FIG. 1. Provided therein are a first, a second, and a third ohmic resistor 10, 12, and 14, respectively, which are connected in series. A first capacitor 16 is connected in parallel to the first resistor 10 and a second capacitor 17 is connected in parallel to the third resistor 14. In addition, an inductance 18 is connected in parallel to the second resistor 12.

Starting from the mentioned knowledge, the method according to the invention comprises the following steps.

An electric signal, which is made up of at least two different frequencies, is applied to the rechargeable battery cell or the rechargeable battery formed from it. These different frequencies are preferably generated in succession. However, it is also conceivable that they are generated simultaneously. Impedance values are determined for the frequency signals by analysis of voltage and current and an impedance curve is calculated from them. Values for an area are then determined, said area resulting from the impedance curve, a threshold value, and the x axis of a coordinate system in which the impedance curve can be plotted. A control signal, the value of which is a measure of the value of the mentioned area, is then generated. In doing so, it is also possible that an additional boundary line is used in determining the area.

It has been found that the value of the mentioned area is a measure of the state of the rechargeable battery or of one or more of its battery cells and is in particular a measure of the ageing as a function of the number of charging/discharging cycles that have already occurred. It is also possible in this way to establish whether a battery which can also be nearly factory new is defective or not.

It has further been found that the value of the area is also a measure of the quality of contacts that are present on or in the battery system. It is thus possible to determine both the quality of new contacts and the ageing of contacts. Such contacts are formed, in particular, through leads to the batteries and/or through connections between individual battery cells contained in the battery.

Further details and advantages will be explained below on the basis of preferred exemplary embodiments by using figures. Shown are:

FIG. 1 an equivalent circuit diagram for a lithium ion accumulator

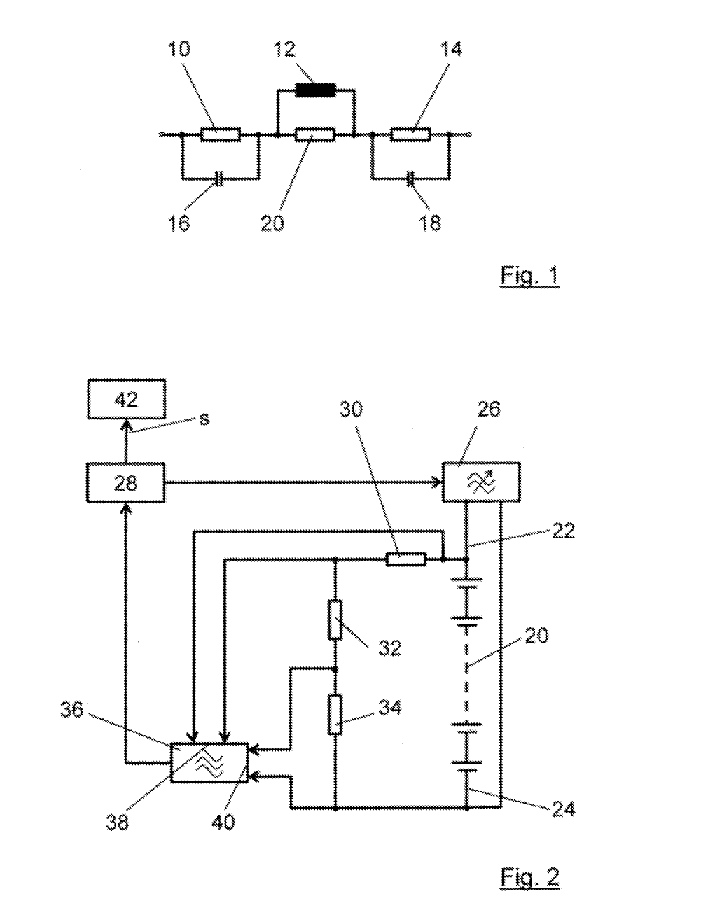

FIG. 2 an apparatus for determining the remaining lifetime of the accumulator

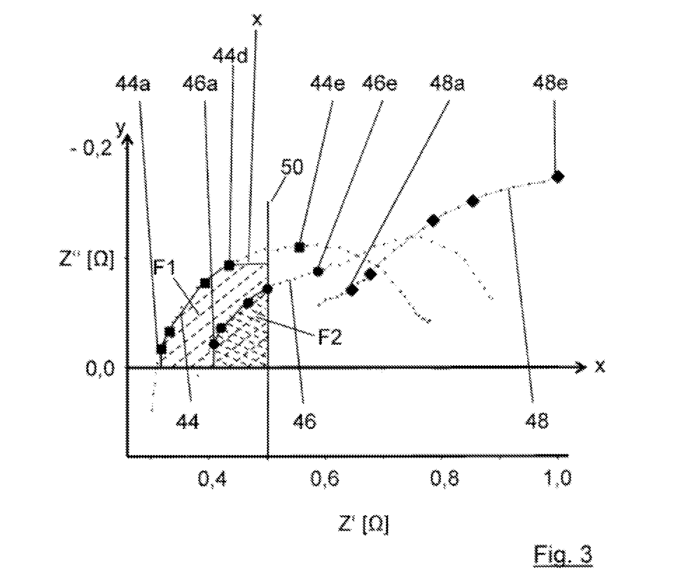

FIG. 3 a diagram with values that result from use of the apparatus according to FIG. 2

FIG. 1 shows a preferred simple equivalent circuit diagram, by means of which the electrical properties of a lithium ion accumulator can be presented and which has already been described above.

Provided in FIG. 2 is a lithium ion accumulator 20. The terminals 22 and 24 thereof are each connected to an output terminal of a frequency generator 26, which can be driven by a control and analysis apparatus 28 referred to below for simplicity as a control apparatus. This control apparatus 28 preferably has an electronic design and comprises a microprocessor (not illustrated here). The first accumulator terminal 22 is connected via a shunt resistor 30 to a first voltage divider resistor 32 and to a second voltage divider resistor 34, which is connected in series and which, in turn, leads to the second accumulator terminal 24. The two resistors 32, 34 can serve as reference resistors. For this purpose, low-capacitance and low-inductance capless carbon film resistors can be used. The two terminals of the shunt resistor 30 are additionally connected to the first input 38 and the two terminals of the second voltage divider resistor 34 are connected to the second input 40 of a frequency filter 36. The control apparatus 28 additionally controls a signal apparatus 42, which is suitable for emitting optical and/or acoustic signals depending on an actuating signal s of the control apparatus 28.

For completeness, it is noted that the following are not illustrated in FIG. 2:
an apparatus for charging and
a consumer, such as a motor vehicle electric motor, for discharging the accumulator 20. These charging and discharging apparatuses are usually present in normal operation.

FIG. 3 shows, on the basis of a Nyquist diagram, values that result when the apparatus according to FIG. 2 is operated and that can be appropriately analyzed.

Plotted in the Nyquist diagram according to FIG. 3 are real values Z′ on the x axis and imaginary values Z″ on the y axis. Drawn therein are three impedance curves 44, 46, 48, which respectively result from five measured values 44a, . . . 44e, 46a, . . . 46e, and 48a, . . . 48e. Additionally plotted in each case are a number of individual values (not specially marked), which were determined by using mathematical algorithms that are known as such and through which one of the curves 44, 46, 48 was drawn in each case. The measured values 44a, . . . 44e relate to an accumulator 20 that is nearly unused, that is, has undergone only a few charging/discharging cycles. The measured values 46a, . . . 46e relate to an accumulator that has already been in operation for some time. Finally, the measured values 48a, . . . 48e relate to an accumulator that has been frequently charged and discharged and whose operational reliability is questionable. The five individual measured values 44a, . . . 44e result from measurements at different frequencies (at 10 kHz, 5 kHz, 1 kHz, 500 Hz, and 100 Hz). The same applies to the measured values 46a, . . . 46e and 48a, . . . 48e. Moreover, a reference line 50 here, at x=0.5 is drawn. It is noted that the above-mentioned frequencies used in this preferred exemplary embodiment are given by way of example. Depending on the accumulator 20 being measured, any combinations of frequencies may be chosen. Choice of suitable frequencies is generally a part of calibration.

In the following, the function of the apparatus shown in FIG. 2 will be explained by using the diagram of FIG. 3.

A nearly unused accumulator 20 will be assumed initially. It is connected as shown in FIG. 2, with apparatuses for charging and discharging not being shown, as already mentioned. The frequency generator 26 is driven by the control apparatus 28 in such a manner that it emits a first frequency with a value of 10 kHz. This results in a first alternating voltage being applied to the accumulator 20 and also the flow of an associated current. A value for the voltage is obtained by a voltage drop at the second voltage divider resistor 34, which is connected to the input 40, and a value for the current is obtained by a voltage drop at the shunt resistor 30, which is connect to the input 38 of the frequency filter 36. Used as frequency filter 36 in a preferred exemplary embodiment is such a type that works according to the principle of impedance spectroscopy. It is capable of determining both the real value and the imaginary value for the first frequency, from which a measured value 44a is obtained, and a corresponding signal is emitted to the control apparatus 28. Once the latter has received such a signal, it drives the frequency generator 26 such that the latter outputs a second frequency with a value of 5 kHz. From this, the frequency filter 36 analogously determines the measured value 44b. In a similar way, the measured values 44c, 44d, and 44e are determined for further frequencies with values of 1 kHz, 500 Hz, and 100 Hz.

The control apparatus 28 analyzes the first measured values 44a, . . . 44e and determines, in accordance with mathematical algorithms that are known as such, the individual values that serve to determine the course of the associated first curve. Depending on the system used, particularly the type of accumulator 20 used, a threshold value is specified beforehand to the control apparatus 28, said threshold value being depicted by the reference line 50 in FIG. 3. Used here for the threshold value preferred for the exemplary embodiment is one that is suitably stored within the control apparatus 28 in a memory, which is not illustrated. Such a threshold value is determined preferably for each accumulator 20. The threshold value should not lie too far to the right. The threshold value can also be determined independently by means of the control apparatus 28, for example, for another or new accumulator during an initialization measurement independently for the accumulator used in each case. Such an initialization method usually works independently of the current state of the accumulator 20 that is used. In this way, it is possible to avoid the necessity of using exclusively factory-new accumulators.

A value for the area F1 is then determined by the control apparatus 28 by means of a numerical integration method, said area resulting from the x axis, the reference line 50, and the first impedance curve 44. In this exemplary embodiment, however, the entire impedance curve 44 that lies to the left of the reference line 50 is not used for determination of the area. Instead, the area F1 was additionally delimited by a boundary line x, which, in this exemplary embodiment, results from a parallel to the x axis, which passes through the last of the measured values 44a, . . . 44e that is situated to the left of the reference line 50 thus, in this case, specifically through the measured value 44d.

In the preferred embodiment, it is assumed that the value of the area F1 is so large that the accumulator 20 is relatively unused and still has a remaining lifetime that is quite long. The control apparatus 28 therefore outputs a corresponding control signal s to the signal apparatus 42. The latter preferably includes an optical indicator, which operates according to the traffic light principle. This means that lamps that light up green, yellow, and/or red can be actuated. On the basis of the first measurement and analysis, the indicator apparatus 42 is thus initially actuated such that it emits green light.

The mentioned measurements and analyses are repeated at predetermined points in time for the accumulator 20. These points in time can occur at regular intervals, such as daily, monthly, or the like. Because the measurement is very quick, it can also occur in minute cycles as needed. It is additionally possible to determine the points in time according to how many charging/discharging cycles have been carried out. Furthermore, it is possible to take into consideration additional operating parameters, such as external temperatures or operating temperatures or the life. Obviously, it is also possible to take into consideration various mentioned parameters jointly in order to determine suitable points in time for carrying out the desired measurements and analyses. For starting the mentioned measurement and analyses, appropriate means (not illustrated here) are included in the control apparatus 28, such as a timer or a temperature measurement means. These can be implemented insofar as possible also by means of programming of the microprocessor, which is not illustrated.

For another measurement and analysis that occurs later than that leading to the measured values 44 or the area F1, the accumulator 20 is appropriately aged on the basis of charging/discharging cycles that have occurred in the interim. These result in analogy to the first measured values 44a, . . . 44e in the second measured values 46a, . . . 46e. Determined from these are the associated second impedance curve 46 and also a value for the associated area F2, which is determined by the position of the second impedance curve 46 in relation to the x axis and in relation to the reference line 50, determined by the control apparatus 28. A reference line similar to the line x for the first impedance curve is not present here, because the reference line 50 passes through one of the measured points 46.

As also can be seen from FIG. 3, the area F2 is smaller than the area F1. The difference of the areas F2−F1 is a measure of the ageing of the accumulator 20 that has occurred. Moreover, the area F2 is a measure of the remaining lifetime of the accumulator 20. In the preferred exemplary embodiment, the signal apparatus 42 is driven in such a manner that it now emits yellow light.

Drawn in FIG. 3 is a third impedance curve 48, which is obtained on the basis of the third measured values 48a, . . . 48e. In this case, it can be seen that this third impedance curve 48 intersects neither the x axis nor the reference line 50. Accordingly, a value for the associated area F3 (not illustrated in FIG. 3, because it does not exist there) is thus obtained. In such a case, the control apparatus 28 would actuate the signal apparatus 42 in such a manner that it emits red light according to the traffic light principle. From this, a user can recognize that the present accumulator 20 and thus the apparatus supplied by it, such as a motor vehicle, can then no longer be operated. It is thus now urgently advisable to commence taking appropriate steps, such as inspection by a qualified workshop, replacement of the accumulator 20, or the like.

The method steps and apparatuses described on the basis of the exemplary embodiments are preferred, but are given only by way of example. It is possible to make alterations, such as, for example:
At least individual apparatuses for measurement and analysis of the values shown in FIG. 3 can be integrated into other components of a motor vehicle, such as in a dashboard computer, a battery system, a battery management system, or the like.
The signal apparatus 42 can additionally or instead also include other means for optical display, with it being possible to display diagrams, such as pie charts, and/or numerical values, such as percents, steps of ten, or the like.
The signal apparatus 42 can additionally or instead also included means for emitting acoustic signals, which, in an appropriate manner such as, for example, by way of various sequences of tones and/or different frequencies indicate to the user the state of the accumulator 20.
For the determination of the boundary value according to line 50, it is also possible to take into consideration the contact of the accumulator 20, since, when there is an alteration in the contact, a parallel shift of the impedance curves 44, 46, 68 usually in the x direction can occur. If the contact resistance for terminals, cables, etc. is smaller than the target value, the entire area F1, F2 shifts to the left; if the contact resistance is greater than the target value, there is a shift to the right.
However, the impedance spectrum usually includes its shape, which also applies to the areas F1, F2.
If problems with the contact resistance are expected, the following procedure can be followed: The reference line 50 can also be determined on the basis of a specific limit frequency and be part of a calibration when the accumulator 20 is placed in operation. This frequency generates an impedance, from which a real resistance can be calculated. This resistance can be taken as a reference point if it is transformed, as in FIG. 2, into a second Y axis (reference line 50). Such a value is stored in the control apparatus 28. It then applies for this specific accumulator for the entire lifetime. Through such a method, it is also possible to characterize very large accumulator assemblies, such as those that are installed in electric motor vehicles, for example. In this way, it is possible to determine for each accumulator its own reference point (reference line 50) or resistance. It is also possible to monitor a plurality of batteries connected in parallel and/or in series by means of a measuring instrument.
When the threshold value is determined according to line 50 and/or the impedance curves 44, 46, 48 are measured, temperature dependences can be taken into consideration. To this end, the following procedure is followed:
   a) The measurements are carried out at constant temperatures (standard temperature).
   b) The measurements are always carried out once a certain temperature has been reached, that is, once the accumulator 50 has attained a specific temperature.
   c) Impedance spectra for different temperatures are determined and associated values are stored in the control apparatus 28, which serve appropriately for analysis.
The mentioned methods can be used individually or else combined with one another.
The boundary line x can also have a different course than that mentioned above. Thus, it is also conceivable, for example, that the reference line x passes through a value differing from the measured values 44a, . . . 44e. The parallel course with respect to the x axis is also given only by way of example.
It is likewise possible that the boundary line x passes through two measured values, one of which is situated to the left and the other of which is situated to the right of the reference line 50, such as, for example, through the measured values 44d and 44e.

### LIST OF REFERENCE SIGNS

10 first ohmic resistor
12 second ohmic resistor
14 third ohmic resistor
16 first capacitor
17 second capacitor
18 inductance
20 lithium ion accumulator
22 first terminal of the accumulator 20
24 second terminal of the accumulator 20
26 frequency generator
28 control and analysis apparatus
30 shunt resistor
32 first voltage divider resistor
34 second voltage divider resistor
36 frequency filter
38 first input of the frequency filter 36
40 second input of the frequency filter 36
42 signal apparatus
44 first impedance curve
44a, . . . 44e first measured value for first curve
46 second impedance curve
46a, . . . 46e second measured value for second curve
48 third impedance curve
48a, . . . 48e third measured value for third curve
50 reference line
s control signal
x reference line

1. A method for determining the state of a rechargeable battery and/or the quality of contacts, wherein a signal with at least two different frequencies is applied to a battery,
hereby characterized in that
a first impedance value is determined for the first of the at least two frequencies, and a second impedance value is determined for the second of the at least two frequencies,
on the basis of the determined impedance values, an impedance curve is determined, which can be represented in a coordinate system with an x axis and a y axis,
a threshold value is determined, which corresponds to a determined x value,
a value for the area is calculated, which results from the impedance curve, the x axis, and the threshold value, and in that
a control signal is generated as a function of the value for the area.

2. The method according to claim 1, further characterized in that the value for the area is a measure for the number of charging/discharging operations of the battery that have occurred and/or for the quality of contacts in a battery system.

3. The method according to claim 1, further characterized in that real values of the impedance values can be represented on the x axis and imaginary values on the y axis.

4. The method according to claim 1, further characterized in that the threshold value is determined by an initialization measurement.

5. The method according to claim 1, further characterized in that the impedance values are determined with the help of the principle of impedance spectroscopy.

6. The method according to claim 1,
further characterized in that, on the basis of the control signal, an optical and/or acoustic signal is generated, which is suitable to indicate to a user the state of the battery.

7. The method according to claim 1, further characterized in that it is carried out at a predetermined point in time and/or as a function of an operating state, such as temperature, for example, the temperature of the accumulator, the ambient temperature, or the like.

8. An apparatus for carrying out a method, hereby characterized in that a control and analysis apparatus is provided, which can drive a frequency generator, the signal of which is applied to the battery, and which can generate at least two different frequencies, in that an apparatus is present, which, on the basis of the signal applied to the battery, can determine the impedance values, and in that analysis means are present, which, on the basis of the determined impedance values determine the impedance curves and the areas and subsequently generate the control signal.

9. The apparatus according to claim 8, further characterized in that a signal apparatus is present, which, depending on the control signal, emits an optical and/or acoustic signal, which is suitable for indicating to a user the state of the battery.

10. The apparatus according to claim 8, further characterized in that a timer is included, which, after expiration of a predetermined time, emits a control signal, as a result of which the above-mentioned method is carried out.

11. The apparatus according to claim 8, further characterized in that temperature measuring means are present, which emit a control signal when a predetermined temperature is reached, as a result of which the above-mentioned method is carried out.

12. The method according to claim 1, further characterized in that the value for the area is a measure for the number of charging/discharging operations of the battery that have occurred and/or for the quality of contacts in a battery system, and in that real values of the impedance values can be represented on the x axis and imaginary values on the y axis.

13. The method according to claim 12, further characterized in that the threshold value is determined by an initialization measurement.

14. The method according to claim 13, further characterized in that the impedance values are determined with the help of the principle of impedance spectroscopy.

15. The method according to claim 14, further characterized in that, on the basis of the control signal, an optical and/or acoustic signal is generated, which is suitable to indicate to a user the state of the battery.

16. The apparatus according to claim 8, further characterized in that a signal apparatus is present, which, depending on the control signal, emits an optical and/or acoustic signal, which is suitable for indicating to a user the state of the battery, and further characterized in that a timer is included, which, after expiration of a predetermined time, emits a control signal, as a result of which the above-mentioned method is carried out.

17. The apparatus according to claim 16, further characterized in that temperature measuring means are present, which emit a control signal when a predetermined temperature is reached, as a result of which the above-mentioned method is carried out.
